(19) United States
(12) Patent Application Publication
(10) Pub. No.: US 2007/0266283 A1
(43) Pub. Date: Nov. 15, 2007

(54) Method and Apparatus for Testing an Integrated Circuit

(75) Inventors: Kedarnath Balakrishnan, Austin, TX (US); Seongmoon Wang, Plainsboro, NJ (US); Wenlong Wei, Mercerville, NJ (US); Srimat T. Chakradhar, Manalapan, NJ (US)

Correspondence Address: NEC LABORATORIES AMERICA, INC., 4 INDEPENDENCE WAY, PRINCETON, NJ, 08540, US

(73) Assignee: NEC LABORATORIES AMERICA, INC., Princeton, NJ (US)

(21) Appl. No.: 11/692,367

(22) Filed: Mar. 28, 2007

Related U.S. Application Data
(60) Provisional application No. 60/746,083, filed on May 1, 2006.

(51) Int. Cl. G01R 31/28

(52) U.S. Cl. 714/726

(57) ABSTRACT

Disclosed is an apparatus and method for testing an IC having a plurality of scan chains. A test input is transmitted over a tester channel to at least one scan chain during a time interval. Specifically, a memory element stores a first test input transmitted during a first time interval and a combinational circuit connected to the memory element and scan chain transmits to the scan chain one of a) the first test input and b) a second test input transmitted over the tester channel during a second time interval occurring after the first time interval.

This application claims the benefit of U.S. Provisional Application No. 60/746,083 filed on May 1, 2006, which is incorporated herein by reference.

### BACKGROUND OF THE INVENTION

The present invention is related generally to integrated circuits, and in particular to the testing of integrated circuits.

Large, complex integrated circuits (ICs) are viable usually because their design meets test as well as functional requirements. Design for test (DFT) (i.e., design techniques that add testability features to an IC) was adopted by designers when automatic test equipment (ATE) (also referred to as testers) was developed to insert test data (also referred to as test patterns) to the IC. The test pattern is typically generated by an automatic test pattern generation (ATPG) tool. Generally, these DFT approaches have little effect on the IC's functional circuitry.

As IC designs have become larger and semiconductor manufacturing processes have changed, the number of test patterns needed to test ICs increased greatly. ICs often contain millions or tens of millions of gates, and test patterns are required to test these gates. Further, smaller geometries and copper interconnects have created previously unaccounted for types of defects. To test these defects, additional test patterns are often needed.

Several issues arise as a result of the large number of test patterns needed to test an IC. First, testers have traditionally been unable to test a complex IC in a single pass. Second, it is becoming increasingly difficult to store the test patterns in the available memory of external testers.

One solution to this memory problem is to increase the memory of the testers. However, the additional memory would increase the cost of already expensive testers. Alternatively, the memory of a tester may be loaded multiple times during a test application. This approach, however, significantly increases the time needed to execute the test application.

Another solution to this problem is to compress the test data. Test data compression schemes rely on the fact that test patterns traditionally contain irrelevant information. Other than a few critical “care-bits”, the rest of the bits (often called “don't care” bits) typically contribute to fault finding by accident. In the past, ATPG tools filled the don't care bits with random 1s and 0s, but the bits still had to be stored in the ATE memory.

Test pattern compression schemes reduce the number of stored bits by supplying the don't care bits in other ways. Some compression schemes are based on coding theory, are independent of ATPG tools, and can achieve high compression. However, the test flow associated with these compression techniques often needs to be significantly modified in order to include the compression scheme. This significant modification to the test flow may discourage the use of these techniques in industrial designs.

The compressed test data is stored on the tester. When an IC is being tested, the compressed test data is loaded onto the IC and decompressed by a special circuit on the IC before being applied to the circuit under test (CUT).

A tester compresses test bits and then transmits the compressed test bits to the IC. Combinational circuits (also called combinational decompressors), such as exclusive OR gates or multiplexors, typically connect a small number of tester channels to the IC's memory element inputs—either directly connecting channels to multiple inputs or combining multiple channels (e.g., using XOR gates). The combinational circuit decompresses the compressed test bits. The architecture of the combinational decompressor is often dependent on the actual test patterns generated by the ATPG tool. As a result, a change in the test patterns (e.g., due to last minute design changes) will often require the combinational decompressor to be redesigned.

FIG. 1 shows a block diagram of an example scan architecture 100 of an IC. This architecture 100 is often referred to as the Illinois scan architecture. To test the IC using test patterns, memory elements of the IC, such as its flip flops, are daisy-chained together to form scan chains. Specifically, the scan architecture 100 includes tester channels 104 (also referred to as scan channels) transmitting test bits from a tester (not shown) to the IC's scan chains, such as chain 1 108, scan chain 2 112, scan chain 4 116 and scan chain 5 120. The test patterns can then be applied to the different scan chains.

There are typically two modes of operation of the scan architecture 100—a parallel (broadcast) mode and a serial mode. In the parallel mode, each tester channel coming from the tester is connected to multiple scan chains. Thus, the same test bit is transmitted to multiple flip-flops in scan chains that are connected to the same tester channel. These are referred to as constraints to the test pattern because scan flip-flops that are driven by the same scan channel and whose scan values are scanned in the same cycle should be assigned the same value in the test pattern by the automatic test pattern generator (ATPG) tool. The ATPG tool takes these constraints into account when generating the test pattern. All faults, however, typically cannot be detected in a parallel mode. As a result, additional test patterns may need to be generated and executed in the serial mode.

In the serial mode, scan chains are configured such that each tester channel drives only one scan chain. One way to do this is to insert multiplexers before some scan chains. For example, in FIG. 1, scan chains 1 108, 2 112, and 5 120 have a corresponding scan chain combinational circuit 124, 128, and 132 positioned before the respective scan chain 108, 112, 120, thereby resulting in longer scan chains (because of a feedback connection (e.g., from the output of scan chain 6 to the input of scan chain 5)). The scan chain combinational circuit 124, 128, 132 can be multiplexers. In the serial mode, there is no constraint on the values that can be assigned to any scan flip-flop.

FIG. 2 shows another example of a scan architecture 200. The scan architecture 200 includes tester channels 204 transmitting test bits from a tester (not shown) to scan chains, such as scan chain 1 208 and scan chain 2 212. In particular, the tester channels 204 transmit the test bits to the scan chains (e.g., scan chains 208, 212) via exclusive OR (XOR) gates, such as XOR gates 216 and 220. The XOR gates transmit the XOR of two test bits transmitted over two tester channels to a scan chain. Thus, the channels that can be assigned to the flip flops of each scan chain (e.g., scan chain 208) are constrained by the values at the tester channels which are taken into account during ATPG.

A disadvantage of using only a combinational circuit such as multiplexor 124 or XOR gate 216 is in the compression that can be achieved. This is because the maximum number of flip-flops that can be assigned in each scan slice (i.e., scan flip-flops in the same shift cycle) is limited by the number of scan channels. Thus, the compression reflects a worst-case scenario with the number of scan channels determining the most highly specified scan slice.

A sequential decompressor, such as a linear feedback shift register (LFSR) or a ring generator, can alleviate this problem because a sequential decompressor typically averages out the worst case by using the tester bits across multiple shift cycles. Nonetheless, a sequential decompressor cannot be integrated with ATPG procedures to generate test patterns because of the large number of variables in the constraints. For example, if an LFSR of size 32 is used, each scan flip-flop can potentially depend on 32 variables that represent the starting state of the LFSR (seed) and generating a test pattern that satisfies the starting state of the LFSR is extremely difficult.

### BRIEF SUMMARY OF THE INVENTION

There remains a need for test data compression/decompression schemes that can easily be integrated with test generation schemes so that little or no modification to the design and test flow is required when, for example, the test pattern changes.

Unlike current solutions, which use combinational circuits to connect a small number of tester scan channels to the scan chain inputs, a limited memory decompressor is used to decompress the compressed test bits in accordance with an aspect of the present invention. A limited memory decompressor is a combinational decompressor that reuses previous test channel values to achieve higher compression without penalties on ATPG complexity.

To test an IC having a plurality of scan chains, a test input is transmitted over a tester channel to at least one scan chain during a time interval. Specifically, a memory element stores a first test input transmitted during a first time interval and a combinational circuit connected to the memory element and scan chain transmits to the scan chain one of a) the first test input and b) a second test input transmitted over the tester channel during a second time interval occurring after the first time interval.

The combinational circuit may include a multiplexor and/or an exclusive OR (XOR) gate. A scan chain combinational circuit connected to the scan chain and the tester channel can be configured to transmit input to the scan chain. The scan chain combinational circuit may be a multiplexor or an XOR gate. Further, the memory element may be in communication with the scan chain via the combinational circuit. In one embodiment, an automatic test equipment (ATE) is in communication with the tester channels and is configured to generate the first and second test inputs.

These and other advantages of the invention will be apparent to those of ordinary skill in the art by reference to the following detailed description and the accompanying drawings.

### BRIEF DESCRIPTION OF THE DRAWINGS

FIG. 1 is a block diagram of an exemplary scan architecture of an integrated circuit (IC) with multiplexers and scan flip-flops;

FIG. 2 is a block diagram of an exemplary scan architecture of an IC with exclusive OR (XOR) gates and scan flip-flops;

FIG. 3 is a block diagram of a scan architecture having a limited memory decompressor, multiplexors, and scan flip-flops in accordance with an embodiment of the present invention;

FIG. 4 is a block diagram of a scan architecture having a limited memory decompressor, XOR gates, and scan flip-flops in accordance with an embodiment of the present invention;

FIG. 5 is a matrix for the limited memory decompressor of FIG. 4 in accordance with an embodiment of the present invention; and

FIG. 6 is a flowchart of the test flow for testing an IC using a limited memory decompressor in accordance with an embodiment of the present invention; and

FIG. 7 is a flowchart showing the steps performed by the scan architecture in accordance with an embodiment of the present invention.

### DETAILED DESCRIPTION

In accordance with an aspect of the present invention, a test input (e.g., a test bit) previously generated for a scan chain of an IC is stored and used more than one time as input to the scan chain. This repeated use of a test input enables higher compression because more test patterns (made up of test inputs) can be stored and compressed by the tester in a given amount of memory. Further, more scan chains can be driven with the same number of scan channels. Additionally, the test generation flow only needs to be modified slightly with this compression scheme.

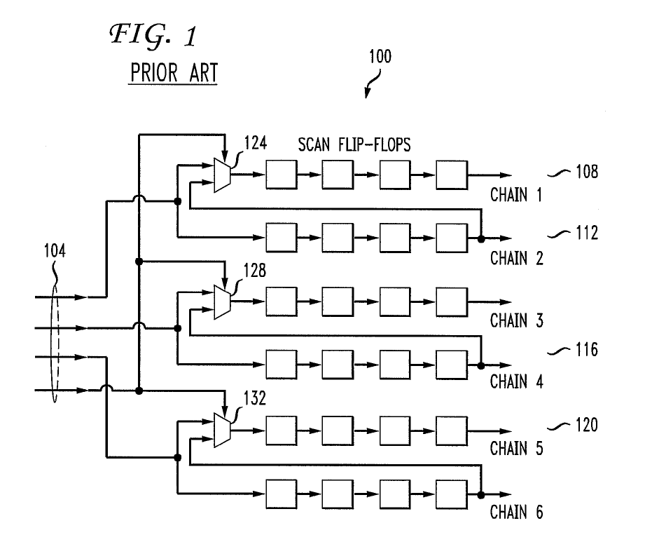

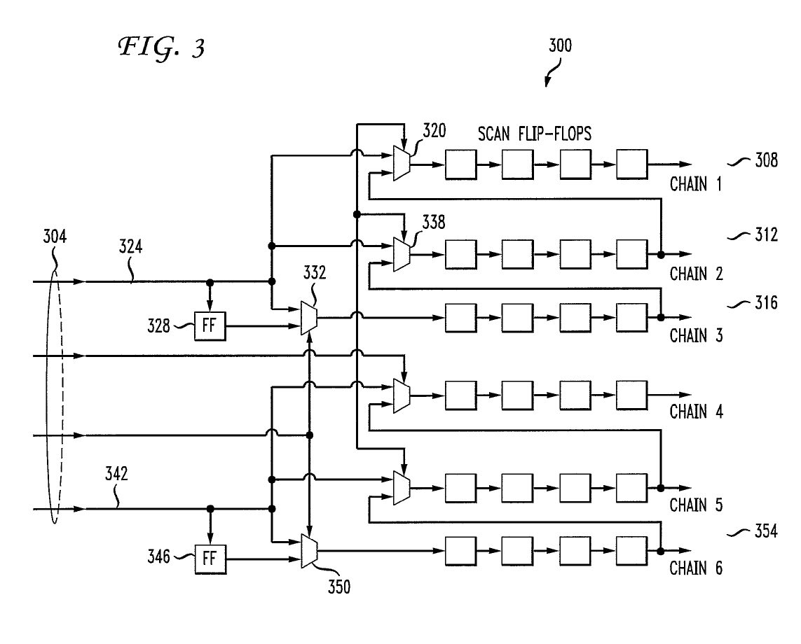

FIG. 3 is a block diagram of a scan architecture 300 in accordance with an embodiment of the present invention. Similar to the Illinois scan architecture 100 described above with respect to FIG. 1, the scan architecture 300 includes tester channels 304 that transmit test input (e.g., test bits) to a plurality of scan chains (e.g., a first scan chain 308, a second scan chain 312, and a third scan chain 316). Each tester channel transmits a test input (e.g., a test bit) to a scan chain within a predetermined time interval (e.g., a clock cycle of the IC's clock circuit). Thus, in two clock cycles, two test inputs (e.g., two test bits) may be transmitted over the same tester channel to a single scan chain.

Also similar to the Illinois scan architecture 100 of FIG. 1, the scan architecture 300 includes scan chain combinational circuits (e.g., multiplexers) positioned before some of the scan chains. For example, a scan chain combinational circuit 320 is located before the scan chain 1 308. The output of the scan chain 2 312 is fed back into the scan chain combinational circuit 320 related to scan chain 1 308. Thus, the scan chain combinational circuit 320 can transmit to the scan chain 1 308 either the output of the scan chain 2 312 or a test input currently transmitted over a first test channel 324 (i.e. during the current clock cycle).

The first test channel 324 is also connected to a memory element 328, such as a flip flop or a register. The memory element 328 is used to store a test input transmitted over the test channel 324 during a previous clock cycle for use during the current clock cycle. The memory element 328 is in communication with a combinational circuit 332. The combinational circuit 332 is also in communication with the tester channel 324. The combinational circuit 332 selects whether to transmit a test input currently being transmitted over the tester channel 324 or the test input stored by the memory element 328 (which was transmitted over the tester channel 324 during a previous clock cycle).

For example, suppose the tester channel 324 is transmitting a first test input during a first clock cycle. The first test input is transmitted to the memory element 328, the combinational circuit 332, as well as the scan chain combinational circuit 320 (and scan chain combinational circuit 338) during a first clock cycle. Thus, the first test input may be transmitted to some of the scan chains (e.g., scan chain 1 308). The first test input is also stored by the memory element 328 during the first clock cycle.

During the next clock cycle (the second clock cycle), the tester channel 304 transmits a second test input (to the combinational circuit 332, the scan chain combinational circuit 320, and the scan chain combinational circuit 338). During the second clock cycle, the memory element 328 transmits the stored first test input to the combinational circuit 332. Thus, the combinational circuit 332 receives the first test input from the memory element 328 and the second test input from the tester channel 324. The combinational circuit 332 then selects (e.g., via a control signal whose values are determined by the ATPG) either the first or second test input to transmit to the scan chain 3 316. The same configuration is also present with respect to tester channel 342, memory element 346, combinational circuit 350, and scan chain 6 354. In one embodiment, the combination of the memory element (e.g., memory element 328 or memory element 346) and combinational circuit (e.g., combinational circuit 332 or combinational circuit 350, respectively) are referred to as a limited memory decompressor.

In one embodiment, the compression that can be obtained by the ATE generating the test inputs is greater when the scan architecture 300 is used with the ATE. The possible compression that can be achieved is greater because previously shifted scan channel values are reused to generate the current scan slice. Unlike sequential decompressors based on LFSRs, the compression scheme associated with the scan architecture 300 has constraints depending on few variables. The scan architecture 300 can be integrated with automatic test pattern generation (ATPG) tools and can incorporate the decompressor constraints in search/backtrace procedures.

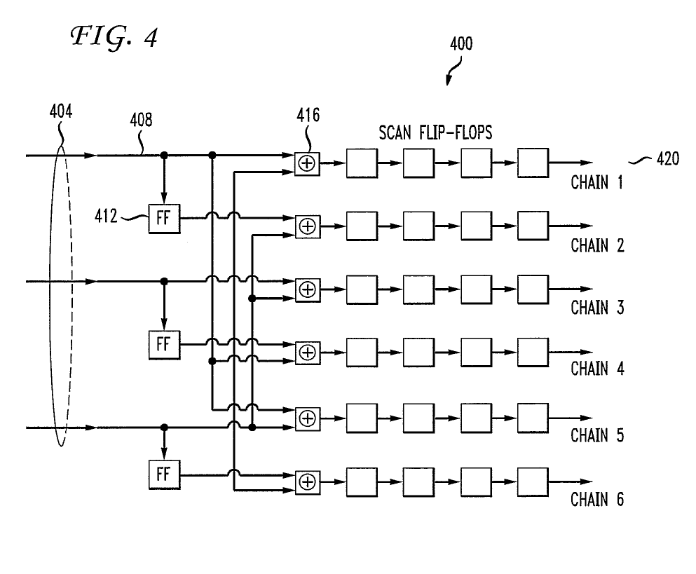

FIG. 4 is a block diagram of another embodiment of a scan architecture 400. The scan architecture 400 includes tester channels 404. Each tester channel (e.g., tester channel 408) is in communication with a memory element (e.g., memory element 412) and a combinational circuit (e.g., combinational circuit 416). The memory element (e.g., memory element 412) and the combinational circuit (e.g., combinational circuit 416) form another embodiment of a limited memory decompressor. The combinational circuits (e.g., combinational circuit 416) may be exclusive OR (XOR) gates (e.g., two input XOR gates) and are each in communication with a scan chain (e.g., scan chain 420).

The memory element 412 and XOR gate 416 (as well as the other memory elements and XOR gates) are used to expand the bits coming in from the tester into several scan chain inputs. By utilizing the previously shifted tester bits, more scan chains can be driven with the same number of scan channels.

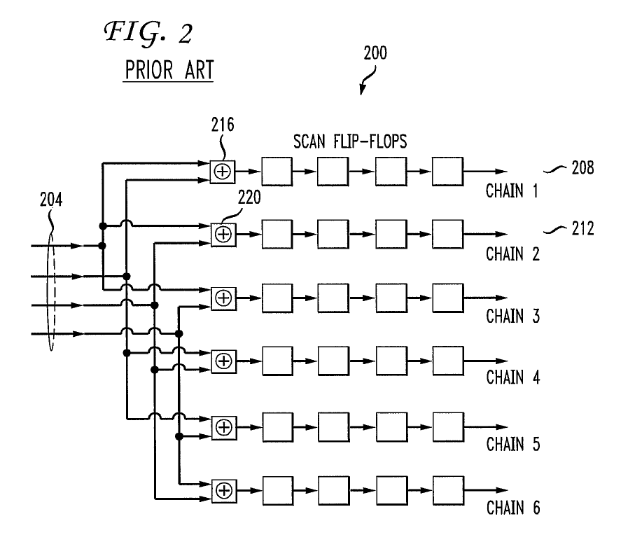

For example, referring again to FIG. 2 and using 2-input XOR gates, (⁴₂)=6 scan chains can be driven with unique combinations. If there are more scan chains, then these combinations have to be repeated. This results in the same constraints for the corresponding flip-flops of the scan chains that have the same combination. If a limited memory decompressor (with depth=1, where depth is the number of previous cycles stored or the number of flip-flops connected serially) is used, however, then the number of unique combinations with the condition that no two scan flip-flops (or memory elements) have the same constraint is given by (⁴₂)+4*4=22. Thus, the number of scan chains that can be driven uniquely using the same number of scan channels increases to 22. In general, a limited memory decompressor of single depth using 2-input

$$m = \frac{( 3 * {n}^{2} - n )}{2}$$

XOR gates can drive up to scan chains, where n represents the depth of the decompressor. If the depth of the decompressor (number of previous cycles stored or number of flip-flops connected serially) is increased, more scan chains can be driven at the cost of hardware overhead.

Limited memory decompressors can additionally handle heavily specified bit slices by reusing previous tester bits. By using combinational circuits as part of the decompressor and having four scan channels, an ATPG tool may not be able to specify any five bits in a scan slice irrespective of the number of specified bits in the previous slice. If a limited memory decompressor is used, however, and if the previous scan slice has less specified bits, then the ATPG may be able to assign more specified bits than the number of scan channels in the current slice. This will improve fault coverage using the compression scheme and increase dynamic compaction of test patterns.

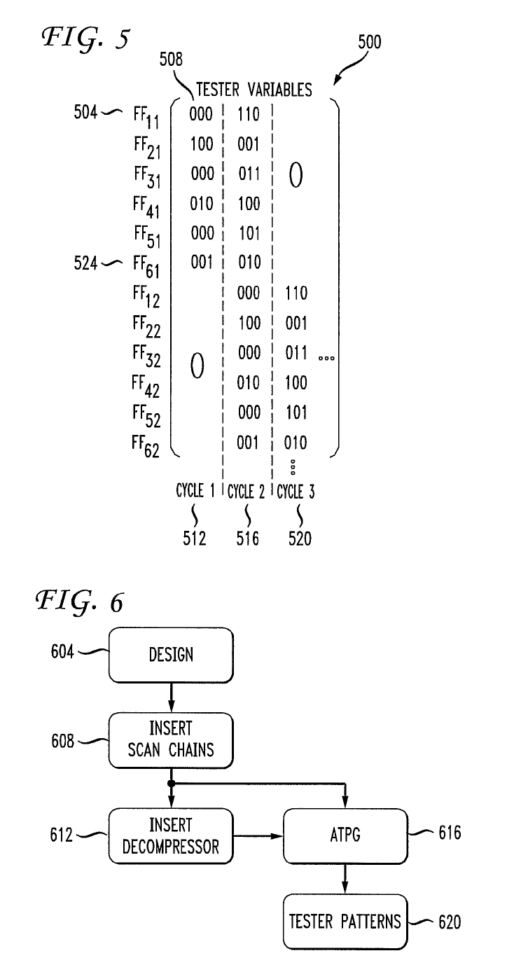

As with combinational decompressors, the relation between the inputs and outputs of the limited memory decompressor can be expressed as a matrix. FIG. 5 shows a matrix 500 for the limited memory decompressor 400 of FIG. 4. Each row (e.g., row FF₁₁ 504) represents an output of a scan flip-flop and each column (e.g., column 508) represents a test input (tester bit).

For combinational decompressors, the matrix 500 is the same for different scan slices. Thus, the same relation between tester scan channels and scan chains is repeated for all of the scan slices. For a limited memory decompressor, however, the dependency is across multiple scan cycles. As shown in FIG. 5, the constraints for scan flip-flops FF₁₁-FF₆₁ depend on tester bits from cycle 1 512 and cycle 2 516. (FF₁₁ denotes first flip-flop of scan chain 1, FF₂₁ denotes first flip-flop of scan chain 2, etc.). Similarly, the constraints for the flip-flops in the second scan slice depend on tester bits from cycle 2 516 and cycle 3 520. Because scan architecture 400 of FIG. 4 has only 2-input XOR gates, there are two 1's in each row of the matrix 500.

Depending on the requirements for the maximum number of specified bits, rules for designing the limited memory decompressor can be formed using error correcting codes. For example, to assign any combination of two specified bits in a single scan slice, the rows corresponding to the scan slice should not be identical. In FIG. 5, none of the rows from row 1 504 to row 6 524 are identical to each other. The calculation above for the maximum number of scan chains that can be driven uniquely using the limited memory decompressor assumes that no two rows are identical across all scan slices. Similarly, the number of scan channels required for a given number of scan chains and different maximum number of specified bits can be calculated.

Note that the number of flip-flops and the depth of the decompressor are design parameters of the compression/decompression scheme. In one embodiment, having more depth improves the compression but requires more hardware overhead for the decompressor and may increase the ATPG run-time.

FIG. 6 is a flowchart showing a test generation flow for a scan architecture having a limited memory decompressor. These steps may be performed by a computer. Adding a limited memory decompressor to a scan architecture requires minimal modification to the test generation flow. The test generation flow includes a design step 604 in which the integrated circuit is designed. The memory elements (e.g., flip flops) of the IC are then configured into a plurality of scan chains in step 608. A limited memory decompressor is inserted into the circuit in step 612. A test pattern is automatically generated in step 616 (e.g., via an ATPG tool) to produce tester (or test) patterns shown with block 620. The only added step relative to a typical test generation flow is the insertion of a limited memory decompressor in step 612.

It is possible, however, that some faults may become untestable using the decompressor and thus a serial mode (similar to Illinois Scan) is required to load the scan chains directly from the tester scan channels.

Even though the placement of scan flip-flops into different scan chains affects the compression of the scan chain architecture with a limited memory decompressor, there is typically no need to modify the scan chain synthesis. The design of the decompressor can be further optimized by taking into account the structure of the circuit-under-test (CUT). The combination of which inputs to XOR for a particular scan chain input may be based on structural information.

In one embodiment, the number of scan shift cycles is increased by the depth of the decompressor. Thus, if a decompressor of depth d is used and the maximum scan chain length is l, then d+l shifts are required to completely fill in the scan chains with the corresponding value. This can ensure that the decompressor flip-flops are reset between test patterns.

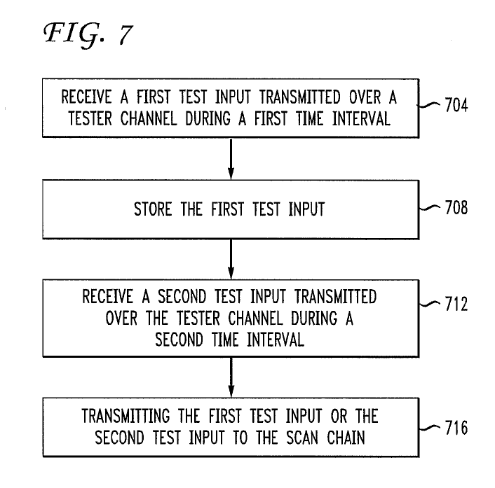

FIG. 7 is a flowchart illustrating the steps performed by a scan architecture in accordance with an embodiment of the present invention. A memory element (e.g., a flip flop) first connected to a tester channel receives a first test input that is transmitted over the tester channel during a first time interval, such as a first cycle of the IC's clock circuit, in step 704. The first test input is stored by the memory element in step 708. After the storing step, a combinational circuit in communication with the memory element and a scan chain and connected to the tester channel receives a second test input transmitted over the tester channel during a second time interval occurring after the first time interval in step 712. The combinational circuit then transmits the first test input or the second test input to the scan chain in step 716.

The foregoing Detailed Description is to be understood as being in every respect illustrative and exemplary, but not restrictive, and the scope of the invention disclosed herein is not to be determined from the Detailed Description, but rather from the claims as interpreted according to the full breadth permitted by the patent laws. It is to be understood that the embodiments shown and described herein are only illustrative of the principles of the present invention and that various modifications may be implemented by those skilled in the art without departing from the scope and spirit of the invention. Those skilled in the art could implement various other feature combinations without departing from the scope and spirit of the invention.

1. An apparatus for testing an integrated circuit (IC), said IC comprising a plurality of scan chains, said apparatus comprising:
a tester channel configured to transmit a first test input to a plurality of scan chains during a first time interval and a second test input to said plurality of scan chains during a second time interval;
a memory element connected to said tester channel and configured to store said first test input; and
a combinational circuit comprising a first input connected to said tester channel, a second input connected to said memory element, and an output connected to a scan chain in said plurality of scan chains, said combinational circuit configured to transmit to said scan chain one of a) said first test input and b) said second test input.

2. The apparatus of claim 1 further comprising a plurality of memory elements, each memory element having an input connected to a tester channel in a plurality of tester channels and an output connected to a combinational circuit in a plurality of combinational circuits.

3. The apparatus of claim 2 wherein each combinational circuit in said plurality of combinational circuits comprises a first input connected to a tester channel in said plurality of tester channels, a second input connected to a memory element in said plurality of memory elements, and an output connected to a scan chain in said plurality of scan chains.

4. The apparatus of claim 1 wherein said combinational circuit further comprises at least one of a multiplexer and an exclusive OR (XOR) gate.

5. The apparatus of claim 1 further comprising a scan chain combinational circuit comprising an input connected to said tester channel and an output connected to said scan chain, and configured to transmit input to said scan chain.

6. The apparatus of claim 5 wherein said scan chain combinational circuit further comprises at least one of a multiplexer and an XOR gate.

7. The apparatus of claim 1 further comprising automatic test equipment (ATE) in communication with said tester channel and configured to generate said first test input and said second test input.

8. A method for testing an integrated circuit (IC), said IC comprising a plurality of scan chains and a tester channel configured to transmit a first test input to said plurality of scan chains during a first time interval and a second test input to said plurality of scan chains during a second time interval, said method comprising:
storing said first test input by a memory element, said memory element comprising an input connected to a tester channel in said plurality and an output connected to a combinational circuit;
receiving said second test input by said combinational circuit, said combinational circuit comprising a first input connected to said output of said memory element, a second input connected to said tester channel, and an output connected to a scan chain in said plurality of scan chains; and
transmitting, by said combinational circuit, one of said first test input and said second test input to said scan chain.

9. The method of claim 8 further comprising selecting said at least one of said first test input and said second test input to transmit to said scan chain.

10. The method of claim 9 wherein said selecting further comprises performing an exclusive OR operation on said first test input and said second test input.

11. An apparatus for testing an integrated circuit (IC), said IC comprising a plurality of scan chains, said apparatus comprising:
means for storing a first test input transmitted over a tester channel to said plurality of scan chains during a first time interval;
means for receiving a second test input transmitted over said tester channel during a second time interval, said means for receiving comprising a first input connected to said output of said means for storing, a second input connected to said tester channel, and an output connected to a scan chain in said plurality of scan chains; and
means for transmitting one of said first test input and said second test input to said scan chain.

12. The apparatus of claim 11 further comprising means for selecting said at least one of said first test input and said second test input to transmit to said scan chain.

13. The apparatus of claim 12 wherein said means for selecting further comprises means for performing an exclusive OR operation on said first test input and said second test input.

14. An apparatus for testing an integrated circuit (IC), said IC comprising a plurality of scan chains, said apparatus comprising:
a tester channel configured to transmit a first test input to said plurality of scan chains during a first time interval and a second test input to said plurality of scan chains during a second time interval; and
a limited memory decompressor comprising an input connected to said tester channel and an output connected to a scan chain in said plurality of scan chains, said limited memory decompressor configured to store said first test input and configured to transmit to said scan chain one of a) said stored first test input and b) said second test input.

15. The apparatus of claim 14 wherein said limited memory decompressor further comprises a memory element and a combinational circuit.

16. The apparatus of claim 14 further comprising a plurality of limited memory decompressors.

17. The apparatus of claim 15 wherein said combinational circuit further comprises at least one of a multiplexer and an exclusive OR (XOR) gate.

18. The apparatus of claim 14 further comprising a scan chain combinational circuit comprising an input connected to said tester channel and an output connected to said scan chain, said scan chain combinational circuit configured to transmit input to said scan chain.

19. The apparatus of claim 18 wherein said scan chain combinational circuit further comprises at least one of a multiplexer and an XOR gate.

20. The apparatus of claim 14 further comprising automatic test equipment (ATE) in communication with said tester channel and configured to generate said first test input and said second test input.
